(19) United States
(12) Patent Application Publication
(10) Pub. No.: US 2025/0362599 A1
(43) Pub. Date: Nov. 27, 2025

(54) COMPOSITE NANOPARTICLE COMPOSITION, COMPOSITE NANOPARTICLE AND PREPARATION METHOD THEREOF, PHOTO-CURING COMPOSITION, COATING AND DISPLAY DEVICE

(71) Applicant: Shenzhen China Star Optoelectronics Semiconductor Display Technology Co., Ltd., Shenzhen (CN)

(72) Inventors: Qinfu ZHU, Shenzhen (CN); Xue BAI, Shenzhen (CN); Chengxiao SUN, Shenzhen (CN); Miao ZHOU, Shenzhen (CN); Lixuan CHEN, Shenzhen (CN)

(73) Assignee: Shenzhen China Star Optoelectronics Semiconductor Display Technology Co., Ltd., Shenzhen (CN)

(21) Appl. No.: 18/790,707

(22) Filed: Jul. 31, 2024

(30) Foreign Application Priority Data
May 24, 2024 (CN) 202410657884.1

(51) Int. Cl. G03F 7/028; C07F 7/12

(52) U.S. Cl. CPC G03F 7/028; C07F 7/121

(57) ABSTRACT

A composite nanoparticle composition, a composite nanoparticle and a preparation method thereof, a photo-curing composition, a coating, and a display device are provided herein. The composite nanoparticle composition includes nanoparticles and a composite modifier. The composite modifier includes a first coupling agent and a second coupling agent, the first coupling agent has a carbon-carbon double bond and the second coupling agent has a —CF₃ group.

### CROSS-REFERENCE TO RELATED APPLICATION

This application claims priority to and the benefit of Chinese Patent Application No. 202410657884.1, filed on May 24, 2024, the disclosure of which is incorporated herein by reference in its entirety.

### TECHNICAL FIELD

The present disclosure relates to display technologies, and in particular, to a composite nanoparticle composition, a composite nanoparticle and a method for preparing the composite nanoparticle, a photo-curing composition, a coating, and a display device.

### BACKGROUND

During the daily use, the display may face many challenges due to the differences in the usage environment. At present, the commonly used technical solution is to vaporize an emulsion of polyvinylidene difluoride (PVDF) or polytetrafluoroethylene (PTEF) into a thin film, and after subjected to drying and other treatments, the thin film is used as the outermost protective layer of the display.

### SUMMARY

Embodiments of the present disclosure provide a composite nanoparticle composition, a composite nanoparticle and a preparation method thereof, a photo-curing composition, a coating, and a display device.

In a first aspect, the present disclosure provides a composite nanoparticle composition, comprising nanoparticles and a composite modifier. The composite modifier comprises a first coupling agent and a second coupling agent, the first coupling agent comprising a carbon-carbon double bond and the second coupling agent comprising a —CF₃ group.

In a second aspect, the present disclosure also provides a method of preparing a composite nanoparticle, comprising:
a step of dissolving the above composite nanoparticle composition and a catalyst in a solvent, obtaining a mixture and
a step of reacting the mixture at a temperature of 20° C. to 80° C., obtaining the composite nanoparticle.

In a third aspect, the present disclosure also provides a composite nanoparticle, the composite nanoparticle comprises a nanoparticle body, a first organic moiety, and a second organic moiety. The first organic moiety is attached to the nanoparticle body and comprises a carbon-carbon double bond. The second organic moiety is attached to the nanoparticle body and comprises a —CF₃ group.

In a fourth aspect, the present disclosure also provides a photo-curing composition comprising the above-described composite nanoparticles, a photo-curing resin, and a photoinitiator.

In a fifth aspect, the present disclosure further provides a coating, the coating is prepared from the photo-curing composition.

A sixth aspect provides a coating comprising a polymer matrix and nanoparticles dispersed in the polymer matrix, the nanoparticles are connected to the polymer matrix via a first organic segment, the nanoparticles are further connected to second organic segment on the surface, the second organic segment comprises a —CF₃ group.

In a seventh aspect, the present disclosure also provides a display device comprising a display panel and a coating as described above, the coating is disposed on a light exit side of the display panel.

### BRIEF DESCRIPTION OF THE DRAWINGS

FIG. 1 is a schematic section diagram of a display device according to embodiments of the present disclosure.

FIG. 2 is a schematic structural diagram of a coating according to embodiments of the present disclosure.

The drawing symbols are shown below:
200, Display device; 11, Display panel; 12, Coating; 121, Polymer matrix; 122, Nanoparticle body; 123, First organic segment; 124, Second organic segment; 13, Functional layer; 131, Protection cover.

### DETAILED DESCRIPTION

The technical solutions in the embodiments of the present disclosure will be clearly and completely described below in conjunction with the appended drawings in the embodiments of the present disclosure. Obviously, the described embodiments are only a portion of the embodiments of the present disclosure and not all of the embodiments. Based on the embodiments in the present disclosure, all other embodiments obtained by a person skilled in the art without creative labor fall within the protection scope of the present disclosure.

In some embodiments of the present disclosure, a composite nanoparticle composition, a composite nanoparticle, and a method of preparing the composite nanoparticle are provided. The nanoparticles are modified by a first coupling agent comprising a carbon-carbon double bond and a second coupling agent comprising a —CF₃ group, and the composite nanoparticles obtained after the modification have a surface attached with the carbon-carbon double bond and the CF₃ group. The carbon-carbon double bond can participate in polymerization reaction, such that the composite nanoparticles are connected to the polymer network, remedying the agglomeration and uplifting issues of the nanoparticle. The CF₃ moiety has good hydrophobicity and oleophobicity and can improve the hydrophobicity and oleophobicity of the composite nanoparticles.

In some embodiments of the present disclosure, a photo-curing composition, a coating and a display device are provided. The carbon-carbon double bond of the composite nanoparticles reacts with the photo-curing resin such that the composite nanoparticles are connected to a polymer network formed by polymerization of the photo-curing resin, remedying the agglomeration and uplifting issues of the composite nanoparticles in the coating. As the composite nanoparticles are connected to the polymer network, the composite nanoparticles have better compatibility with the polymer network and the polymer network is essentially non-crystallizing, resulting in the coating with a low haze, which reduces the displaying haze of the display device. Moreover, since the composite nanoparticles themselves have hydrophobicity and oleophobicity, and the surface of the coating has better oleophobicity due to the fact that the uplifted nanoparticles become concave and convex, the coating has good hydrophobicity and oleophobicity. The hydrophobicity and oleophobicity of the coating improves the hydrophobicity and oleophobicity of the surface of the display device.

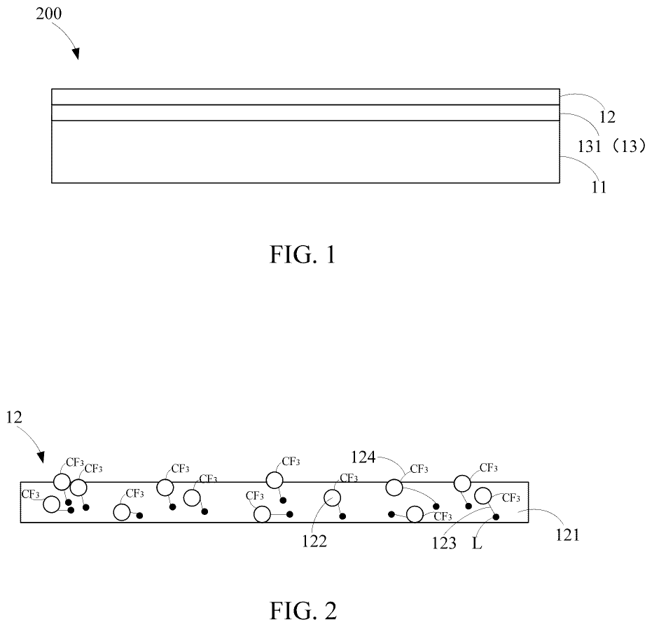

With reference to FIG. 1, it shows a schematic diagram of a cross-sectional structure of a display device of some embodiments provided by the present disclosure. The display device 200 includes a display panel 11 and a coating 12. The coating 12 is disposed on the light exit side of the display panel 11.

The display panel 11 may be any one of an organic light-emitting diode display panel, a liquid crystal display panel, a quantum dot display panel, a micro light-emitting diode display panel, or a sub-millimeter light-emitting diode display panel.

The coating 12 may be the outermost layer at the light exit side of the display device 200, but is not limited thereto. During usage of the display device 200, the user is in direct contact with the coating 12, which protects the display device 200. The coating 12 is required to have a high hardness as well as good abrasion resistance to ensure that the display device 200 is scratch resistant. The coating 12 is also required to be hydrophobic and oleophobic to ensure that the display device 200 has good hydrophobicity and oleophobicity. In addition, the coating 12 is required to have high light transmission and low haze to ensure the display effect of the display device 200.

It is noted that the coating 12 may also be disposed at other locations of the display device 200, such as inside the display panel 11, between the display panel 11 and the functional layer 13, or, on the back side of the light exit surface of the display panel 11.

The display device 200 may also include a functional layer 13 disposed between the coating 12 and the display panel 11. The functional layer 13 may include at least one of a protective cover 131, a polarizer, a touch layer, or an ultra-thin glass.

In some embodiments, as shown in FIG. 1, the functional layer 13 may include a protective cover 131, with the coating 12 disposing on a surface of the protective cover 131 away from the display panel 11 and in contact with the protective cover 131. The protective cover 131 may include a transparent glass cover. The protective cover 131 may also include a transparent polymer cover.

In other embodiments, the functional layer 13 may include a polarizer, and the coating 12 may be disposed on a surface of the polarizer away from the display panel 11 and in contact with the polarizer.

In other embodiments, the coating 12 may also be disposed on, and in direct contact with, the light emitting surface of the display panel 11. In this way, the coating 12 serves to protect the display device 200 while thinning the thickness of the display device 200 and ensuring the display effect of the display device 200.

In some embodiments, the thickness of the coating 12 may range from 1 micron to 6 microns. In this way, the coating 12 can protect the display panel while also ensuring the transmittance of the light emitted from the display panel 11 therethrough. Optionally, the thickness of the coating 12 may range from 2 microns to 5 microns. The thickness of the coating 12 is too thin to be protective. The thickness of the coating 12 is too thick to be conducive to reducing the thickness of the display device 200 and increasing the transmittance of the light.

With reference to FIG. 2, it shows a schematic structural diagram of the structure of some embodiments of coatings provided by the present disclosure. The coating 12 comprises a polymer matrix 121 and nanoparticle bodies 122 dispersed in the polymer matrix 121, with the nanoparticle bodies 122 being dispersed in the polymer matrix 121. A portion of the nanoparticle bodies 122 may be disposed within the polymer matrix 121, and another small portion of the nanoparticle bodies 122 may be disposed on the surface of the polymer matrix 121.

The nanoparticle body 122 and the polymer matrix 121 may be connected by a first organic segment 123, and the connection point between the first organic segment 123 and the polymer matrix 121 is shown at point L in FIG. 2. In this way, there is better compatibility between the nanoparticle body 122 and the polymer matrix 121, increasing the light transmittance of the coating 12 and decreasing the haze of the coating 12, which in turn enhances the display brightness of the display device 200 and improves the haze of the display device 200 when it is displayed.

The surface of the nanoparticle body 122 is further connected to a second organic segment 124. The second organic segment 124 comprises a —CF₃ group, and the second organic segment 124 is hydrophobic and oleophobic such that the coating 12 is also hydrophobic and oleophobic. The second organic segment 124 may be different from the first organic segment 123 and not connected to the first organic segment 123. The second organic segment 124 may also be connected to the first organic segment 123.

In some embodiments, the second organic segment 124 may comprise at least one of a straight chain perfluoroalkyl group having from 1 to 20 carbon atoms or a branched perfluoroalkyl group having from 3 to 20 carbon atoms. In this way, the second organic segment 124 may include a CF₃ group and the second organic segment 124 is sufficiently flexible.

Optionally, the second organic segment 124 may comprise at least one of a straight chain perfluoroalkyl group having from 5 to 20 carbon atoms or a branched perfluoroalkyl group having from 6 to 20 carbon atoms. Optionally, the second organic segment 124 may comprise at least one of a straight chain perfluoroalkyl group having from 8 to 20 carbon atoms or a branched perfluoroalkyl group having from 8 to 20 carbon atoms. In this way, while ensuring that the second organic segment 124 comprises CF₃ groups, the second organic segment 124 has sufficient length, such that the second organic segment 124 connected to the nanoparticle body 122 inside the coating 12 can extend to the surface of the coating 12 to better enhance the hydrophobicity and oleophobicity of the surface of the coating 12.

Optionally, the second organic segment 124 may comprise a branched perfluoroalkyl group having from 3 to 20 carbon atoms. In this way, the second organic segment 124 may include more CF₃ groups to ensure better hydrophobicity and oleophobicity, and the second organic segment 124 may also have better flexibility.

Among them, the linear perfluoroalkyl group having 1 to 20 carbon atoms may comprise trifluoromethyl, pentafluoroethyl, heptafluoro-n-propyl, nonafluoro-n-butyl, undecafluoro-n-pentyl, tridecafluoro-n-hexyl, pentafluoro-n-heptyl, heptadecafluoro-n-octyl, nondecafluoro-n-nonyl, twenty-one fluoro-n-decyl, perfluoro-n-undecyl, perfluoro-n-dodecyl, perfluoro-n-tridecayl, perfluoro-n-tetradecyl, perfluoro-n-pentadecyl, perfluoro-n-hexadecyl, perfluoro-n-heptadecanyl, perfluoro-n-octadecyl, perfluoro-n-nadecayl, perfluoro-n-eicosanyl, etc. Optionally, the second organic segment 124 may comprise pentadecafluoro-n-heptyl, heptadecafluoro-n-octyl, nondecafluoro-n-nonyl, heneicosafluoro-n-decyl, perfluoro-n-undecanyl to ensure that while the second organic segment 124 includes CF₃ groups, the second organic segment 124 has sufficient length, and the second organic segment 124 connected to the nanoparticle body 122 inside the coating 12 may extend to the surface of the coating 12 so as to better improve the hydrophobicity and oleophobicity of the surface of the display device 200.

Among them, the branched perfluoroalkyl groups having 3 to 20 carbon atoms include heptafluoroisopropyl, ninafluoro-sec-butyl, ninafluoro-tert-butyl, perfluoro-2-methylhexyl, perfluoro-tert-octyl, and the like. Optionally, the second organic segment 124 may include perfluoro-tert-octyl to ensure that the second organic segment 124 includes a sufficiently large number of CF₃ groups while ensuring that the second organic segment 124 is longer and thus may extend to the surface of the coating 12 so as to ensure hydrophobicity and oleophobicity of the surface of the display device 200.

In some embodiments, the polymer matrix 121 may comprise a polyacrylate. In this way, the molding speed of the coating 12 may be increased and the mechanical properties of the coating 12 can be ensured. And, the polymer matrix 121 is made to have good light transmittance.

In some embodiments, the polymer matrix 121 may further comprise at least one of a urethane polyacrylate, a polyester polyacrylate, or a cured epoxy acrylate. In this way, the mechanical properties of the polymer matrix 121 can be enhanced, which in turn ensures that the polymer matrix 121 has greater hardness and better abrasion resistance, and that the polymer matrix 121 may have good light transmittance, lower haze, and resistance to stress inward contraction.

In a specific embodiment, the polymer matrix 121 may comprise the polyacrylate and the urethane polyacrylate. The polyurethane polyacrylate is rigid and flexible, which can make the coating 12 both rigid and somewhat flexible. The rigidity improves the wear resistance of the coating and the flexibility improves the shrinkage of the coating caused due to internal stresses. The polyacrylate in combination with the urethane polyacrylate improves the molding speed of the coating 12, and the coating 12 combines hardness and a certain degree of flexibility, simplifies the manufacturing process of the display device 200, and ensures the abrasion resistance and stress shrinkage resistance of the coating 12.

In some embodiments, the surface of the nanoparticle body 122 may also be connected with reactive hydroxyl groups (not shown). The nanoparticle body 122 may be selected from at least one of silicon oxide, aluminum oxide, titanium dioxide, or zirconium oxide. Optionally, the nanoparticle body 122 may be silicon oxide. A smaller difference in the refractive indices of the silicon oxide and the glass cover plate is more conducive to making the difference in the refractive indices between the coating 12 and the glass cover plate smaller, and to improving the transmittance of light emitted from the display panel 11 through the coating 12.

In some embodiments, the nanoparticle body 122 has a size ranging from 10 nanometers to 200 nanometers. Optionally, the nanoparticle body 122 has a size ranging from 20 nanometers to 150 nanometers. Optionally, the nanoparticle body 122 has a size ranging from 40 nanometers to 120 nanometers.

The above structural design of the coating 12 can make each of the optical properties, mechanical properties, hydrophobic and oleophobic properties, and anti-stress shrinkage properties of the coating 12 improved, ensuring that the coating 12 serves to protect the display device 200 while also improving the display effect of the display device 200.

In some embodiments, the coating 12 has a haze less than or equal to 2.5%. In this way, the haze of the coating 12 is reduced, and in turn the haze of the display device 200 is reduced during the display process, ensuring the display effect of the display device 200. Optionally, the coating 12 has a haze less than or equal to 2.1%. Optionally, the coating 12 has a haze less than or equal to 1.5%. Optionally, the coating 12 has a haze less than or equal to 1.9%. Optionally, the coating 12 has a haze less than or equal to 1.1%.

It is noted that the haze of the coating 12 is related to whether the polymer matrix 121 of the coating 12 is crystallized. The higher the crystallinity of the coating 12, the larger the haze. For example, polyvinylidene fluoride or polytetrafluoroethylene films are highly crystalline, such that the polyvinylidene fluoride or polytetrafluoroethylene films have a haze greater than or equal to 10. In the present disclosure, however, the polymer matrix 121 is substantially non-crystalline, which ensures that the polymer matrix 121 has a low haze.

And, in the case where the coating 12 comprises the nanoparticle body 122 and the polymer matrix 121, the haze of the coating 12 also depends on the compatibility between the nanoparticle body 122 and the polymer matrix 121. The better the compatibility between the nanoparticle body 122 and the polymer matrix 121, the lower the haze of the coating 12. The less the compatibility between the nanoparticle body 122 and the polymer matrix 121, the larger the haze of the coating 12. In the present disclosure, the nanoparticle body 122 has good compatibility in the polymer matrix 121 since the nanoparticle body 122 is connected to the polymer matrix 121 via the first organic segment 123.

In some embodiments, the coating 12 has a transmittance of greater than or equal to 90% for the light having a wavelength from 380 nanometers to 780 nanometers. In this way, the light emitted from the display panel 11 has a larger transmittance through the coating 12, which can enhance the display brightness of the display device 200. Optionally, the coating 12 has a transmittance of greater than or equal to 91% for the light having a wavelength of 380 nanometers to 780 nanometers. Optionally, the coating 12 has a transmittance of greater than or equal to 95% for the light having a wavelength of 380 nanometers to 780 nanometers.

It should be noted that the light transmittance of the coating 12 is primarily related to whether or not the polymer matrix 121 is crystallized. In the case where the polymer matrix 121 is not crystallized, the coating 12 has a higher light transmittance. For example, the polyvinylidene fluoride or polytetrafluoroethylene film has a high degree of crystallinity such that the polyvinylidene fluoride or polytetrafluoroethylene film has a transmittance of less than or equal to 83% for the light having a wavelength of 380 nm to 780 nm. In contrast, in the present disclosure, the polymer matrix 121 may be substantially uncrystallized, allowing the polymer matrix 121 to have a higher transmittance of light.

In some embodiments, as shown in FIG. 2, the coating 12 may have a nanoscale concave and convex structure on both the surface of the coating 12 away from the display panel 11 and the surface of the coating 12 near the display panel 11. The convex structure is mainly formed by the nanoparticle body 122 uplifting to the surface of the coating 12, and the concave structure is located in the region where there is no uplifted nanoparticle body 122. The nanoscale concave and convex structure creates a lotus leaf effect, and the nanoscale concave and convex structure has better hydrophobicity and oleophobicity.

In some embodiments, the design of the first organic segment 123, the second organic segment 124, the nanoparticle body 122, and the polymer matrix 121, in combination with the concave and convex structure of the surface of the coating 12, can result in the coating 12 having a water contact angle greater than or equal to 135° and the coating 12 having an oil contact angle greater than or equal to 100°. In this way, the coating 12 has good hydrophobicity and oleophobicity, and the display device 200 has better hydrophobicity and oleophobicity. Optionally, the coating 12 has a water contact angle greater than or equal to 138° and the coating 12 has an oil contact angle greater than or equal to 105°. Optionally, the coating 12 has a water contact angle greater than or equal to 141° and the coating 12 has an oil contact angle greater than or equal to 110°.

In some embodiments, the coating 12 has a pencil hardness greater than or equal to 2H. In this way, the coating 12 has a high hardness, such that the abrasion resistance of the coating 12 is improved, and the scratch resistance of the display device 200 is significantly improved. Optionally, the coating 12 has a pencil hardness greater than or equal to 3H.

It is noted that the pencil hardness of the coating 12 is primarily related to the bulk structure of the polymer matrix 121 in the coating 12, the crosslinking density, and the added amount of nanoparticles. The more rigid the main structure and the larger the cross-linking density, the pencil hardness will increase accordingly. When the mass of the nanoparticle body 122 increases, the hardness changes slightly.

In order to obtain the above-described coating 12, the present disclosure also provides a photo-curing composition. The coating 12 is prepared from the photo-curing composition. The photo-curing composition comprises a photo curing resin, the composite nanoparticle, and a photoinitiator.

The photo-curing resin may comprise a multifunctional acrylic monomer. In this way, the reaction rate of the photo-curing resin can be accelerated, and the cross-linking density of the photo-curing resin can be increased thereby improving the mechanical properties of the coating 12.

Among them, the multifunctional acrylic monomer may include at least one of two acrylate groups, more than two acrylate groups, two methacrylate groups, or more than two methacrylate groups. For example, the multifunctional acrylic monomer may include one or more of ethylene glycol dimethacrylate (EGDMA), trimethylolpropane trimethacrylate (TMPTMA), pentaerythritol triacrylate (PETA), pentaerythritol tetraacrylate (PETEA), ethoxylated trimethylolpropane triacrylate (EO-TMPTA), propoxylated trimethylolpropane triacrylate (PO-TMPTA), propoxylated triglyceride triacrylate (PO-GLYTA), dipentaerythritol pentaacrylate (DPEPA), or dipentaerythritol hexaacrylate (DPHA). Optionally, the multifunctional acrylic monomer may include at least one of dipentaerythritol hexaacrylate or pentaerythritol triacrylate to increase the reaction rate of the photo-curing resin and to increase the cross-linking density of the photo-curing resin, thereby improving the mechanical properties of the coating 12.

In some embodiments, the photo curing resin may further comprise at least one of a urethane acrylate, an epoxy acrylate, or a polyester acrylate. In this way, the mechanical properties, the reaction rate and so on of the polymer matrix 121 are adjusted. Optionally, the photo-curing resin may further comprise a urethane acrylate. The cured urethane acrylate has a rigidity and flexibility, which may remedy shrinkage caused due to internal stresses generated during the curing of multifunctional acrylic monomers.

In some embodiments, the mass of the urethane acrylate is greater than the mass of the multifunctional acrylic monomer in the photo-curing composition. This is done so as to balance the mechanical properties and the light transmittance of the coating 12 and also to reduce the haze of the coating 12. In a specific embodiment, the mass ratio of the multifunctional acrylic monomer to the urethane acrylate is (10 to 20): (20-50).

In some embodiments, the photoinitiator may be selected from at least one of 2-hydroxy-2-methyl-1-phenyl-1-propanone (photoinitiator 1173), benzophenone, diphenylethanol ketone, diphenylethanedione, 1-hydroxycyclohexylphenylketone, monoacylphosphine oxide, or diacylphosphine oxide.

In some embodiments, the composite nanoparticle comprises the nanoparticle body 122, the first organic moiety, and the second organic moiety. The first organic moiety is attached to the nanoparticle body 122, and the second organic moiety is attached to the nanoparticle body 122. The first organic moiety comprises a carbon-carbon double bond. The second organic group comprises a —CF₃ group.

In some embodiments, the number of the second organic moiety may be greater than the number of the first organic moiety. This is done so as to make the composite nanoparticles have better hydrophobicity and oleophobicity, resulting in better hydrophobicity and oleophobicity of the coating 12 and the surface of the display device 200.

In some embodiments, the molar ratio of the carbon-carbon double bond to —CF₃ group is 1: (0.8 to 1.1) in the composite nanoparticles. In this way, it can be made possible to have a better compatibility between the nanoparticle body 122 and the polymer matrix 121 after the composite nanoparticles are reacted with the photo-curing resin. And, the composite nanoparticles comprise a sufficiently large number of —CF₃ groups.

In some embodiments, the first organic moiety may be represented by a formula of R1-(CH₂)ₚ-SiQ₂-O—, R1 may be CH₂═CHCOOO— or CH₂═C(CH₃)COO—, Q is an alkoxy group, and p is an integer ranging from 0 to 10. This is done so as to facilitate the reaction of the first organic moiety of the composite nanoparticles with the photo-curing resin.

In some embodiments, the second organic moiety may be R₂—(CH₂)_{q}—SiZ₂—O—, R₂ comprises a —CF₃ group, Z is an alkoxy group, and q is an integer ranging from 0 to 20. This is done so that the second organic moiety may comprise a —CF₃ group. Optionally, R₂ may comprise at least one of a straight chain perfluoroalkyl group having from 1 to 20 carbon atoms or a branched perfluoroalkyl group having from 3 to 20 carbon atoms.

In the present disclosure, the alkoxy group may include an alkoxy group having from 1 to 20 carbon atoms. Optionally, the alkoxy group may include an alkoxy group of 1 to 10 carbon atoms. Optionally, the alkoxy group may include an alkoxy group of 1 to 8 carbon atoms. Optionally, the alkoxy group may include an alkoxy group of 1 to 6 carbon atoms. For example, alkoxy group may include methoxy, ethoxy, propoxy, and the like.

It should be noted that the first organic segment 123 is obtained by reacting the carbon-carbon double bond of the first organic moiety with the photo-curing resin. The second organic moiety may not be involved in the polymerization reaction and the second organic segment 124 is identical to the second organic moiety.

In some embodiments, the photo-curing composition may further comprise a first solvent. The first solvent may include at least one of an alcohol, an ester, a ketone, or alkyl benzene. Among others, the alcohol includes, but is not limited to, at least one of methanol, ethanol, or isopropanol. The ester includes, but are not limited to, at least one of ethyl acetate, propyl acetate, or butyl acetate. The ketone includes, but are not limited to, at least one of acetone, butanone, or cyclohexanone. The alkyl benzene includes, but is not limited to, at least one of toluene or xylene. Optionally, the first solvent comprises butyl acetate.

In some embodiments, the photo-curing composition comprises, by weight: polyurethane acrylic resin 20 parts to 50 parts; multifunctional acrylic monomer 10 parts to 20 parts; the composite nanoparticles 5 parts to 30 parts; the photoinitiator 2 parts to 10 parts; and the first solvent. This is done so as to enhance the mechanical properties of the polymer matrix 121, which in turn ensures that the polymer matrix 121 has greater hardness and abrasion resistance, and that the polymer matrix 121 has greater mechanical properties. abrasion resistance, and that the polymer matrix 121 can exhibit good light transmittance, lower haze, and resistance to stress inward contraction.

In some embodiments, the photo-curing composition comprises, by weight, 25 parts to 50 parts of a polyurethane acrylic resin; 12 parts to 18 parts of a multifunctional acrylic monomer; 10 parts to 28 parts of the composite nanoparticles; 3 parts to 8 parts of a photoinitiator; and the first solvent. This is done so as to enhance the mechanical properties of the polymer matrix 121, thereby ensuring that the polymer matrix 121 has greater hardness and wear resistance, and that the polymer matrix 121 can exhibit good light transmittance, lower haze, and resistance to stress inward shrinkage.

In some embodiments, the photo-curing composition may also comprise an adjuvant agent to facilitate molding of the coating 12, or to improve the properties of the coating 12. The adjuvant agent may include a leveling aid. The adjuvant agent may also include an antifouling aid and the like. The photo-curing composition comprises 0.5 parts to 1 part, by weight, of the leveling aid.

In some embodiments, the method of preparing and obtaining the coating 12 from the photo-curing composition comprises: dissolving the photo-curing resin, the composite nanoparticle and the photoinitiator in a first solvent, mixing well, obtaining a mixed solution; coating the mixed solution into a film and removing the first solvent to obtain an initial coating and photo curing the initial coating to obtain the coating 12.

In some embodiments, to obtain the composite nanoparticle, the present disclosure also provides a composite nanoparticle composition. The composite nanoparticle is prepared from the composite nanoparticle composition. The composite nanoparticle composition comprises nanoparticles and a composite modifier. The composite modifier comprises a first coupling agent and a second coupling agent. The first coupling agent comprises a carbon-carbon double bond. The second coupling agent comprises a —CF₃ group. In this way, the molar ratio of the carbon-carbon double bond and the —CF₃ group can be controlled by adjusting the mass of the first coupling agent and the second coupling agent.

In some embodiments, the nanoparticles have a hydroxyl group on the surface to facilitate the reaction of the first coupling agent and the second coupling agent with the hydroxyl group of the nanoparticles so as to obtain the composite nanoparticle. The nanoparticles may be selected from at least one of silica, aluminum trioxide, titanium dioxide, and zirconium oxide.

In some embodiments, the mass ratio of the nanoparticles, the first coupling agent and the second coupling agent is 1: (0.5 to 0.8): (0.8 to 1.2). In this way, the mass sum of the first coupling agent and the second coupling agent is greater than the mass sum of the nanoparticles, ensuring that the first coupling agent and the second coupling agent can sufficiently react with the hydroxyl groups on the surface of the nanoparticles. Moreover, the second coupling agent has larger mass, and more second coupling agent can react with the nanoparticles, which makes the modified composite nanoparticles have more CF₃ groups attached on the surface of the nanoparticles. The composite nanoparticles have better hydrophobic and oleophobic properties. The coating 12 including the composite nanoparticles also has better hydrophobic and oleophobic properties. The surface of the display device 200 including the coating 12 also has good hydrophobic and oleophobic properties.

It is noted that the number of hydroxyl groups on the surface of the nanoparticles is certain, and when both the first coupling agent and the second coupling agent react with the hydroxyl groups, the mass of the first coupling agent is less than the mass of the second coupling agent, which allows more second coupling agent to react with the nanoparticles so as to improve the hydrophobic and oleophobic properties of the composite nanoparticles.

In some embodiments, the first coupling agent is represented by a chemical formula YSiX₃, with Y comprising a carbon-carbon double bond and X being an alkoxy group. Optionally, Y may be R₁—(CH₂)ₚ—, with R₁—(CH₂)ₚ-being the portion of the first organic moiety.

In some embodiments, the second coupling agent is represented by the chemical formula M (CH₂)ₙSiN₃, Mis a perfluoroalkyl group having a number of carbon atoms ranging from 1 to 20, N is an alkoxy group, and n is an integer ranging from 0 to 20.

In some embodiments, the method of preparing the composite nanoparticles comprises: dissolving the catalyst with the nanoparticles and the composite modifier in a second solvent, mixing well, and reacting the same at a temperature of 20° C. to 80° C., and then drying the resultant to obtain the composite nanoparticles.

In some embodiments, the method of preparing the composite nanoparticles may also include: dissolving the catalyst, one of the first coupling agent and the second coupling agent, and the nanoparticles in a second solvent and treating the same for a first predetermined time duration at a temperature of 20° C. to 80° C.; then, adding the other of the first coupling agent and the second coupling agent and treating the same for a second predetermined time duration at a temperature of 20° C. to 80° C.; finally, drying the resultant, obtaining the composite nanoparticles. In some embodiments, the second predetermined time duration is longer than the first predetermined time duration to ensure that the other of the first coupling agent and the second coupling agent reacts more fully with the nanoparticles.

In a specific embodiment, the method of preparing the composite nanoparticles may further include: dissolving the catalyst, the first coupling agent, and the nanoparticles in a second solvent and treating the same for a period of time at a temperature of 20° C. to 80° C.; then adding the second coupling agent and treating the same for a period of time at a temperature of 20° C. to 80° C.; and finally, drying the resultant, obtaining the composite nanoparticles.

In some embodiments, the second solvent comprises at least one of an alcohol, an ester, a ketone, or alkyl benzene. Among others, the alcohol includes, but is not limited to, at least one of methanol, ethanol, or isopropanol. The ester includes, but is not limited to, at least one of ethyl acetate, propyl acetate, or butyl acetate. The ketone includes, but is not limited to, at least one of acetone, butanone, or cyclohexanone. The benzene includes, but is not limited to, at least one of toluene or xylene. Optionally, the second solvent includes butyl acetate.

In some embodiments, the catalyst may include an acid. The acid includes, but not limited to, acetic acid and propionic acid, among others. Optionally, the catalyst comprises acetic acid.

As such, for the above composite nanoparticle composition, the composite nanoparticle, and the method of preparation thereof, the nanoparticles are modified by a first coupling agent comprising a carbon-carbon double bond and a second coupling agent comprising a —CF₃ group, and the composite nanoparticles obtained after the modification have a surface connected to the carbon-carbon double bond and the CF₃ moiety. The carbon-carbon double bond can participate in polymerization reaction, such that the composite nanoparticles are connected to the polymer network, remedying the agglomeration and uplifting issues of the nanoparticles. The CF₃ moiety has good hydrophobicity and oleophobicity and can improve the hydrophobicity and oleophobicity of the composite nanoparticles.

As for the above photo-curing composition, the coating and the display device, the carbon-carbon double bond of the composite nanoparticles reacts with the photo-curing resin such that the composite nanoparticles are connected to a polymer network formed by polymerization of the photo-curing resin, remedying the agglomeration and uplifting issues of the composite nanoparticles in the coating. As the composite nanoparticles are connected to the polymer network, the composite nanoparticles have better compatibility with the polymer network and the polymer network is essentially non-crystallizing, resulting in the coating with a low haze which reduces the displaying haze of the display device. Moreover, since the composite nanoparticles themselves have hydrophobicity and oleophobicity, and the surface of the coating has better oleophobicity due to the fact that the uplifted nanoparticles become concave and convex, the coating has good hydrophobicity and oleophobicity. The hydrophobicity and oleophobicity of the coating improves the hydrophobicity and oleophobicity of the surface of the display device.

The preparation method and properties of the coatings are described below in connection with specific embodiments and comparative embodiments.

The following silane coupling agent KH570, nano-silica, methoxy (1H,1H,2H,2H-heptadecafluorodecyl) silane, pentaerythritol triacrylate (PETA) and dipentaerythritol hexaacrylate (DPHA) each were purchased from Aladdin. Acetic acid and butyl acetate were purchased commercially. Polyurethane acrylate DIC V-4025 was purchased from DIC Co. 2-hydroxy-2-methyl-1-phenyl-1-propanone (photoinitiator 1173) was purchased from Merck. The commercially available antifouling layer was purchased from Zhejiang Juhua and is of the polyvinylidene fluoride (PVDF) type with a molecular weight of 20 k-30 k.

### Embodiment I

This embodiment provides a method of preparing a composite nanoparticle, comprising the following steps:
7 g of silane coupling agent KH570 (the silane coupling agent comprising carbon-carbon double bond) was added to 100 mL of butyl acetate with 10 g of silica nanoparticles and 0.2 mL of acetic acid, mixed homogeneously, and heated to 55° C.˜ 65° C., and the reaction was carried out for 20 h. Then, 0.2 mL of acetic acid and 10 g of trimethoxy (1H, 1H,2H,2H-heptadecafluorodecyl) silane (the silane coupling agent comprising-CF₃) were added, mixed homogeneously, and reacted for 22 h at 55° C.˜65° C., and the butyl acetate was removed to obtain the composite nanoparticles.

### Embodiment II

This embodiment provides a method of preparing a composite nanoparticle. This embodiment is substantially similar to Embodiment I except that the weight/amount of the silane coupling agent KH570 is 3 g.

### Embodiment III

This embodiment provides a method of preparing a composite nanoparticle. This embodiment is substantially similar to Embodiment I except that the silane coupling agent KH570 is 12 g.

### Embodiment IV

This embodiment provides a photo-curing composition comprising, by weight,

| | | |
|---|---|---|
| polyurethane acrylate DIC V-4025 | 40 | parts; |
| pentaerythritol triacrylate PETA | 15 | parts; |
| 2-hydroxy-2-methyl-1-phenyl-1-propanone | 5 | parts; |
| the composite nanoparticles of Embodiment 1 | 20 | parts; |
| the leveling aid BYK 333 | 0.5 | parts; and |
| butyl acetate | 100 | parts. |

The method of preparing the photo-curing composition into a coating in this embodiment comprises: the photo-curing composition in this embodiment is mixed well to obtain a mixed solution; and the mixed solution is coated into a film on the substrate, the butyl acetate was removed, and after UV irradiation, a coating with a thickness of 3 microns to 3.2 microns was obtained.

### Embodiment V

Embodiment V provides a photo-curing composition. The photo-curing composition in this Embodiment is substantially similar to that in Embodiment IV, except that the composite nanoparticles of Embodiment I are replaced with the composite nanoparticles of Embodiment II.

The method of preparing the photo-curing composition into a coating in this embodiment is the same as that in Embodiment IV.

### Embodiment VI

Embodiment VI provides a photo-curing composition. The photo-curing composition of this embodiment is substantially similar to that of Embodiment IV, except that the composite nanoparticles of Embodiment I are replaced with the composite nanoparticles of Embodiment III.

The method of preparing the photo-curing composition in this Embodiment into a coating is the same as that in Embodiment IV.

### Embodiment VII

The present embodiment provides a photo-curing composition comprising, by weight:

| | | |
|---|---|---|
| polyurethane acrylate DIC V-4025 | 35 | parts; |
| dipentaerythritol hexaacrylate DPHA | 20 | parts; |
| 2-hydroxy-2-methyl-1-phenyl-1-propanone | 5 | parts; |
| the composite nanoparticles of Embodiment I | 15 | parts; |
| leveling aid BYK 333 | 0.5 | parts; and |
| butyl acetate | 100 | parts. |

The method of preparing the photo-curing composition into the coating in this embodiment is the same as that in Embodiment IV.

### Embodiment VIII

This embodiment provides a photo-curing composition comprising, by weight:

| | | |
|---|---|---|
| polyurethane acrylate DIC V-4025 | 50 | parts; |
| pentaerythritol triacrylate PETA | 10 | parts; |
| 2-hydroxy-2-methyl-1-phenyl-1-propanone | 5 | parts; |
| composite nanoparticles of Embodiment 1 | 10 | parts; |
| leveling aid BYK 333 | 0.5 | parts; and |
| butyl acetate | 100 | parts. |

The method of preparing the photo-curing composition of this embodiment into a coating is the same as that of Embodiment IV.

### Embodiment IX

The present embodiment provides a photo-curing composition comprising, by weight:

| | | |
|---|---|---|
| polyurethane acrylate DIC V-4025 | 20 | parts; |
| pentaerythritol triacrylate PETA | 20 | parts; |
| 2-hydroxy-2-methyl-1-phenyl-1-propanone | 5 | parts; |
| composite nanoparticles of Embodiment I | 30 | parts; |
| leveling aid BYK 333 | 0.5 | parts; and |
| butyl acetate | 100 | parts. |

The method of preparing the photo-curing composition into the coating in this Embodiment is the same as that in Embodiment IV.

### Embodiment X

The present embodiment provides a photo-curing composition, comprising, by weight:

| | | |
|---|---|---|
| polyurethane acrylate DIC V-4025 | 30 | parts; |
| pentaerythritol triacrylate PETA | 10 | parts; |
| 2-hydroxy-2-methyl-1-phenyl-1-propanone | 2.5 | parts; |
| composite nanoparticles of Embodiment I | 7.5 | parts; |
| leveling aid BYK 333 | 0.5 | parts; and |
| butyl acetate | 100 | parts. |

The method of preparing the photo-curing composition of this Embodiment into the coating is the same as that of Embodiment IV.

### Comparative Embodiment I

Comparative Embodiment I is substantially similar to Embodiment IV, except that the composite nanoparticles in Comparative Embodiment I are different from the composite nanoparticles in Embodiment IV. The preparation method of the composite nanoparticles in Comparative Embodiment I is substantially similar to the preparation method of the composite nanoparticles in Embodiment I, except that there is no 7 g of silane coupling agent KH570, i.e., 10 g of silica nanoparticles are only modified with 10 g of trimethoxy (1H,1H,2H,2H-heptadecafluorodecyl) silane to obtain the composite nanoparticles.

### Comparative Embodiment II

Comparative Embodiment II is substantially similar to Embodiment IV, except that the composite nanoparticles in Comparative Embodiment II are different from the composite nanoparticles of Embodiment IV. The preparation method of the composite nanoparticles in Comparative Embodiment II is substantially similar to the preparation method of the composite nanoparticles in Embodiment I, except that there is no 10 g of trimethoxy (1H, 1H,2H,2H-heptadecafluorodecyl) silane, i.e., 10 g of silica nanoparticles are only modified with 7 g of silane coupling agent KH570 to obtain the composite nanoparticles.

### Comparative Embodiment III

This Embodiment provides a commercially available antifouling layer.

The following tests were performed on the above Embodiments IV through X and on Comparative Embodiments I through III.

Pencil hardness test:
1) Place the test specimen upward and fix it, scratch firmly the coating of the test specimen with a pencil loaded with a 500 g load at an angle of 45° relative to the coating without breaking the lead core, and scratch the coating about 1 cm towards the front of the tester at a constant speed. The speed of scratching is 1 mm/s. After scratching once, the tip of the lead core should be reground, and the test is repeated five times with a pencil of the same hardness marking.
2) Observe the breakage of the coating of the test specimen for evaluation: when the substrate is visible in only 2 or less out of the 5 tests, the same test should be performed with a pencil with a one-digit larger hardness mark, and when the coating is broken in more than 2 tests (for the 5 tests performed), the hardness mark of the pencil at that time may be read and the one-digit smaller hardness mark than the pencil's hardness mark may be noted down as the result of the test. For example, if the substrate is visible only 2 or less times out of 5 tests at a pencil hardness of 2H, the test is changed to a pencil with a pencil hardness of 3H; and if the coating is broken in more than 2 out of 5 tests at a pencil hardness of 3H, the pencil hardness of 2H is noted down as the test result.

Abrasion resistance test:
1) Place the test sample upwards and fix it, fix a small square of 2 cm*2 cm with a test rod above the test sample, use a tie to wrap No. 0 steel wool on the small square, then place a 1000 g weight above the test rod, then lower the test rod to contact the coating of the test sample to start the test. The friction speed is 40 revolutions/minute, the friction distance is 10 cm, and the same test sample is to be tested 2 times to exclude the test bias;
2) Observe the breakage of the coating on the test specimen for evaluation, if the number of scratches per test is less than 10, the test is judged as 1 kg/50 passes; if the number of scratches per test is greater than or equal to 10, the test is judged as 1 kg/50 failures.

Water contact angle test:
1) Preparation of test samples: the test samples for measuring the water contact angle are cleaned and the impurities and grease on the surface are removed.
2) Treatment of test water: The test water is filtered to ensure that the test water is clean and pure and that no other substances are added.
3) Measurement of the water contact angle: The cleaned test sample is placed on the platform, 20 μL-50 μL of test water is dripped onto the coating of the test sample using a micro-sampler, the image of the water droplet is captured with a video camera, and the water contact angle of the water droplet on the image is measured using the relevant software.

Oil contact angle test:
The oil contact angle test method is substantially similar to the water contact angle test method, except that the water is replaced with edible oil.

Transmittance test:
Test the transmittance in accordance with standard ASTM D1003 with NDH-7000 from Nippon Denshi Co.

Haze test:
Test the haze in accordance with standard ASTM D1003 with NDH-7000 from Nippon Denshi Co.

TABLE 1
Test results for Embodiments IV through X
and Comparative Embodiments I through III

| | | | Water | Oil | | |
|---|---|---|---|---|---|---|
| | Pencil | Abrasion | contact | contact | Transmittance | |
| | hardness | resistance | angle (°) | angle (°) | (%) | Haze (%) |
| Embodiment | 3H | 1 kg/50 | 141 | 112 | 92 | 1.5 |
| IV | | passes | | | | |
| Embodiment | 2H | 1 kg/50 | 139 | 110 | 92 | 1.3 |
| V | | passes | | | | |
| Embodiment | 3H | 1 kg/50 | 138 | 111 | 92 | 1.4 |
| VI | | passes | | | | |
| Embodiment | 3H | 1 kg/50 | 144 | 109 | 92 | 1.8 |
| VII | | passes | | | | |
| Embodiment | 3H | 1 kg/50 | 146 | 113 | 91 | 1.2 |
| VIII | | passes | | | | |
| Embodiment | 3H | 1 kg/50 | 138 | 107 | 92 | 1.9 |
| IX | | passes | | | | |
| Embodiment | 3H | 1 kg/50 | 138 | 108 | 92 | 1.1 |
| X | | passes | | | | |
| Comparative | HB | 1 kg/10 | 139 | 115 | 92 | 1.5 |
| Embodiment | | failures | | | | |
| I | | | | | | |
| Comparative | 2H | 1 kg/50 | 90 | 60 | 92 | 1.9 |
| Embodiment | | passes | | | | |
| II | | | | | | |
| Comparative | HB | 1 kg/10 | 145 | 115 | 83 | 10 |
| Embodiment | | failures | | | | |
| III | | | | | | |

As can be seen in conjunction with Table 1, the pencil hardness of the coatings of Embodiments IV to X is greater than or equal to 2H, which is greater than the pencil hardness of the commercially available antifouling layer of Comparative Embodiment III. Moreover, the coatings of Embodiments IV to X can pass a 1 kg/50 passes abrasion resistance test. Thus, the coatings of some embodiments of the present disclosure have good hardness and wear resistance.

The coatings of Embodiments IV to X have a transmittance of greater than or equal to 91% and a haze of less than or equal to 1.9% as compared to Comparative Embodiment III. Thus, the coatings of some embodiments of the present disclosure have good optical properties.

The coatings of Embodiments IV through X have a water contact angle greater than or equal to 138° and an oil contact angle greater than or equal to 107°. Thus, the coatings of some embodiments of the present disclosure have good hydrophobicity and oleophobicity.

In addition, a comparison of Comparative Embodiment I with Embodiments IV through X shows that treating the nanoparticles only with a silane coupling agent comprising-CF₃ group results in a coating with poorer pencil hardness and abrasion resistance. Comparison of Comparative Embodiment II with Embodiments IV through X shows that treatment of the nanoparticles with only the silane coupling agent comprising the carbon-carbon double bond resulted in the coatings with smaller water contact angle and oil contact angle.

The above description of the embodiments is merely intended to help understand the method and core ideas of the present disclosure. It can be understood that for those of ordinary skill in the art, it is also possible to modify the technical solutions described in each of the embodiments above; or make the equivalent replacements to part of the technical features therein; and all these modifications or replacements would not render the essence of the technical solutions depart from the scope of the technical solutions in each of the embodiments of the present disclosure.

What is claimed is:

1. A composite nanoparticle composition, comprising:
nanoparticles;
a composite modifier, wherein the composite modifier comprises a first coupling agent and a second coupling agent, the first coupling agent comprises a carbon-carbon double bond and the second coupling agent comprises a —CF₃ group.

2. The composite nanoparticle composition according to claim 1, wherein a mass ratio of the nanoparticles: the first coupling agent: the second coupling agent ranges from 1: (0.5-0.8): (0.8-1.2).

3. The composite nanoparticle composition according to claim 1, wherein the first coupling agent is represented by a formula of YSiX₃, wherein Y is an ethylenically unsaturated group comprising a carbon-carbon double bond and X is an alkoxy group;
the second coupling agent is represented by a formula of M (CH₂)ₙSiN₃, wherein M is a perfluoroalkyl group having 1 to 20 carbon atoms, N is an alkoxy group, and n is an integer ranging from 0 to 20.

4. The composite nanoparticle composition according to claim 1, wherein each of the nanoparticles have a hydroxyl group on a surface.

5. The composite nanoparticle composition according to claim 3, wherein the alkoxy group has 1 to 20 carbon atoms.

6. A method of preparing a composite nanoparticle, comprising:
dissolving the composite nanoparticle composition according to the claim 1 and a catalyst in a solvent to obtain a mixture; and
reacting the mixture at a temperature ranging from 20° C. to 80° C. to obtain the composite nanoparticle.

7. A composite nanoparticle comprising:
a nanoparticle body;
a first organic moiety, wherein the first organic moiety is connected to the nanoparticle body and comprises a carbon-carbon double bond; and
a second organic moiety, wherein the second organic moiety is connected to the nanoparticle body and comprises a —CF₃ group.

8. The composite nanoparticle according to claim 7, wherein the first organic moiety is represented by R1—(CH₂)ₚ-SiQ₂-O—, wherein R1 is CH₂═CHCOO— or CH₂═C(CH₃)COO—, Q is an alkoxy group, and p is an integer ranging from 0 to 10, and wherein the second organic moiety is represented by R2-(CH₂)_{q}—SiZ₂—O—, wherein R2 comprises a —CF₃ group, Z is an alkoxy group, and q is an integer ranging from 0 to 20.

9. A photo-curing composition comprising:
the composite nanoparticle according to claim 7;
a photo-curing resin; and
a photoinitiator.

10. The photo-curing composition according to claim 9, wherein the photo-curing resin comprises a polyfunctional acrylic monomer.

11. The photo-curing composition according to claim 10, wherein the photo-curing resin further comprises at least one selected from a group consisting of a urethane acrylate, an epoxy acrylate, and a polyester acrylate.

12. The photo-curing composition according to claim 10, wherein the photoinitiator is at least one selected from a group consisting of 2-hydroxy-2-methyl-1-phenyl-1-propanone, benzophenone, diphenylethanol ketone, diphenylethanedione, 1-hydroxycyclohexylphenylketone, monoacylphosphine oxide, and diacylphosphine oxide.

13. The photo-curing composition according to claim 11, wherein, by weight, the photo-curing composition comprises:

| | |
|---|---|
| the polyurethane acrylic resin | 20 parts to 50 parts; |
| the polyfunctional acrylic monomer | 10 parts to 20 parts; |
| the composite nanoparticle | 5 parts to 30 parts; and |
| the photoinitiator | 2 parts to 10 parts. |

14. A coating comprising a polymer matrix and nanoparticles dispersed in the polymer matrix, wherein each of the nanoparticles is connected to the polymer matrix by a first organic segment, and each of the nanoparticles is further connected to a second organic segment on a surface, and the second organic segment comprises a —CF₃ group.

15. A display device comprising:
a display panel; and
the coating according to the claim 14, disposed on a light exit side of the display panel.

16. The display device according to claim 15, wherein the coating has a haze of less than or equal to 2.5%.

17. The display device according to claim 15, wherein the coating has a transmittance of greater than or equal to 90% for a light having a wavelength ranging from 380 nm to 780 nm.

18. The display device according to claim 15, wherein the coating has a water contact angle of greater than 135° and the coating has an oil contact angle of greater than or equal to 100°.

19. The display device according to claim 15, wherein the coating has a pencil hardness of greater than or equal to 2H.
